(19) United States
(12) Patent Application Publication
(10) Pub. No.: US 2008/0057850 A1
(43) Pub. Date: Mar. 6, 2008

(54) Mask for manufacturing a display device

(75) Inventor: Chong Hyun Park, Buk-gu (KR)

Correspondence Address: KED & ASSOCIATES, LLP, P.O. Box 221200, Chantilly, VA, 20153-1200, US

(73) Assignee: LG Electronics Inc.

(21) Appl. No.: 11/637,774

(22) Filed: Dec. 13, 2006

(30) Foreign Application Priority Data
Sep. 4, 2006 (KR) 10-2006-0084677

(51) Int. Cl. H05K 5/00

(52) U.S. Cl. 454/184

(57) ABSTRACT

A mask for compensating transformation of grills included in each of a plurality of grill sections is provided. The mask includes a plurality of grill sections in each of which at least one grill is formed. Some or all of the at least one grill formed in a first grill section are inclined. The first grill section is one of outermost grill sections of the plurality of grill sections. In the mask, the grills deformed by a stretching force may have the same shape as normal grills to which the stretching force is not applied during a stretching process. Accordingly, in the process of evaporating an organic layer, the layer may be accurately evaporated on desired portions of a substrate.

### CROSS-REFERENCE TO RELATED APPLICATIONS

This application claims priority from Korean Patent Application No. 2006-84677, filed on Sep. 4, 2006, the contents of which are incorporated herein by reference in its entirety.

### BACKGROUND OF THE INVENTION

1. Field of the Invention

The present invention relates to a mask for manufacturing a display device. More particularly, the present invention relates to a mask for compensating deformation of grills included in each of grill sections.

2. Description of the Related Art

A mask is used in a process of evaporating organic layer 3 of a process of manufacturing an organic electroluminescent device which is one of display devices, wherein the organic layer 3 is evaporated on pixel areas (hereinafter, referred to as “active areas”) of a substrate, and is made up of an organic material corresponding to red light, green light or blue light.

FIG. 1 is a plan view illustrating a common mask employed in a process of manufacturing an organic electroluminescent device.

A mask 10 is composed of a plurality of grill sections 12, 12-1, 13 and 13-1 corresponding to active areas of a substrate, wherein the mask 10 has dimension corresponding to whole area of the substrate.

FIG. 2 is a view illustrating in detail “B” portion in FIG. 1, and shows the grill section 12 formed in an upper-left corner of the mask 10.

As shown in FIG. 2, the grill section 12 is made up of a plurality of grills 12A-1 to 12A-5 penetrating a mask base member 11.

The grills 12A-1 to 12A-5 have the same length and width, and disposed in parallel one another with constant space between adjacent grills.

Organic material vapor corresponding to red light, green light or blue light generated from a evaporation source is evaporated on the substrate through the grills 12A-1 to 12A-5.

Before performing an evaporation process using the above mask, a stretcher stretches the mask 10 in all directions so that uniform tension is applied to the whole area of the mask 10.

That is, under condition of fixing outer portion of the mask 10 using a plurality of grippers (not shown), the grippers are stretched outside of the mask 10 in the direction of arrow in FIG. 1. As a result, the mask 10 has uniform tension distribution through the whole area thereof, and so deformation such as sag, deflection, etc is not occurred to a mask base member 11.

The mask 10 is fixed to a rectangular frame (not shown) by using for example an ultrasonic welding under the above condition, and then a scribing process is performed along a scribing line L. Consequently, an outer portion of the mask base member 11 where a grill section is not formed is removed. Subsequently, the process of evaporating an organic layer is performed by using the mask 10 (fixed to the frame) manufactured by the above process.

In the above stretching process of the mask 10, the grippers connected to a driving means grips each of edges of the mask 10, and each of the grippers stretches the mask 10 in the direction of arrow in FIG. 1.

However, deformation, e.g. distortion is necessarily occurred to the grills 12A-1 to 12A-5 formed on the mask base member 11 by an external force in the stretching process of the mask 10 as shown in FIG. 1 and FIG. 2.

FIG. 3A and FIG. 3B are partial views illustrating the grill sections formed the corners of the mask to which a stretching force is applied by the grippers. Particularly, FIG. 3A shows the grill section 12 formed on an upper-left corner of the mask 10 in FIG. 2. FIG. 3B shows the grill section 13 formed on a lower-left corner of the mask 10.

On the other hand, arrows in FIG. 3A and FIG. 3B indicate directions of the stretching force applied by the grippers which grips the edge portion of the mask 10.

As shown in FIG. 3A and FIG. 3B, an area (11-1 in FIG. 3A and 11-2 in FIG. 3B, hereinafter, referred to as “solid area”) in which grill is not formed exits in an upper portion and an lower portion of the grill sections 12 and 13 formed on the upper and lower corners of the mask base member 11. The deformation conditions of the grills 12A-1 to 12A-5, and 13A-1 to 13A-5 of the grill sections 12 and 13 are different in accordance with the solid areas 11-1 and 11-2 in the stretching process.

Particularly, when the stretching force by the grippers is applied to each of the grills 12A-1 to 12A-5, little deformation is occurred to an upper portion corresponding to the solid area 11-1 of each of the grills 12A-1 to 12A-5 formed on the upper corner. However, a lower portion of each of the grills 12A-1 to 12A-5 is moved, i.e. deformed in the direction of outside of the mask 10, wherein the deformation is shown as dotted line in FIG. 3A.

Whereas, when the stretching force by the grippers is applied to each of the grills 13A-1 to 13A-5, little deformation is occurred to a lower portion corresponding to the solid area 11-2 of each of the grills 13A-1 to 13A-5 formed on the lower corner. However, an upper portion of each of the grills 13A-1 to 13A-5 is moved, i.e. deformed in the direction of outside of the mask 10, wherein the deformation is shown as dotted line in FIG. 3B.

As shown in FIG. 3A and FIG. 3B, since the stretching force is applied to grill, e.g. 12A-1 or 13A-1 disposed in an lateral portion of the grills 12A-1 to 12A-5, or 13A-1 to 13A-5 earlier than the other grills 12A-2 to 12A-5, or 13A-2 to 13A-5, the stretching force applied to the grill, e.g. 12A-1 or 13A-1 is higher than that applied to the grills 12A-2 to 12A-5, or 13A-2 to 13A-5. Accordingly, the deformation degree of the grill, e.g. 12A-1 or 13A-1 is higher than that of the grills 12A-2 to 12A-5, or 13A-2 to 13A-5.

Additionally, when the stretching force is applied to the grill section 12-1 adjacent to the grill section 12 formed on the upper corner of the mask base member 11, the deformation degree of a portion adjacent to the solid area 11-1, i.e. an upper portion of each of grills of the grill section 12-1 is smaller than that of a lower portion of each of the grills of the grill section 12-1.

Further, when the stretching force is applied to the grill section 13-1 adjacent to the grill section 13 formed on the lower corner of the mask base member 11, the deformation degree of a portion adjacent to the solid area 13-1, i.e. a lower portion of each of grills of the grill section 13-1 is smaller than that of an upper portion of each of the grills of the grill section 13-1.

Deformation opposed to the above deformation is occurred to grill sections formed in an upper-right corner and a lower-right corner of the mask 10 in FIG. 1.

Hence, since the deformation is occurred to the grills of the mask 10, the organic layer may not be formed accurately when the mask 10 is employed in the evaporation process.

Accordingly, it is desirable to minimize the deformation of the grills 12A-1 to 12A-5, and 13A-1 to 13A-5 and difference of deformation degree between the grills 12A-1 to 12A-5, or 13A-1 to 13A-5 in the stretching process.

### BRIEF DESCRIPTION OF THE DRAWINGS

The above and other features and advantages of the present invention will become readily apparent by reference to the following detailed description when considered in conjunction with the accompanying drawings wherein:

FIG. 1 is a plan view illustrating a common mask employed in a process of manufacturing an organic electroluminescent device;

FIG. 2 is a view illustrating in detail “B” portion in FIG. 1;

FIG. 3A and FIG. 3B are partial views illustrating the grill sections formed the corners of the mask to which a stretching force is applied by the grippers;

FIG. 4A and FIG. 4B are views illustrating a part of a mask according to one embodiment of the present invention; and

FIG. 5A and FIG. 5B are views illustrating in detail the grill sections in FIG. 4A and FIG. 4B.

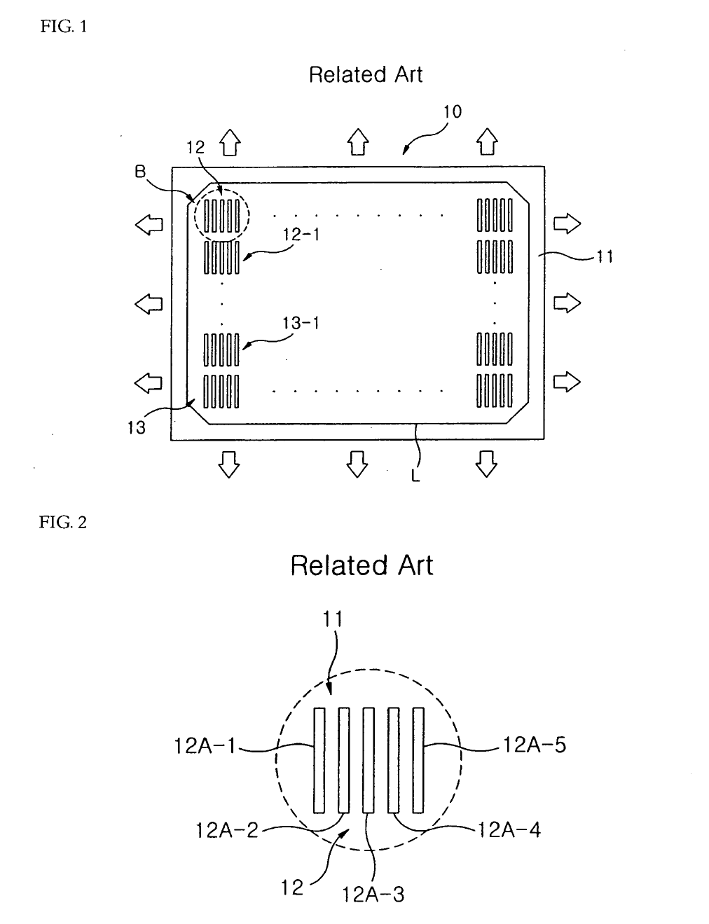

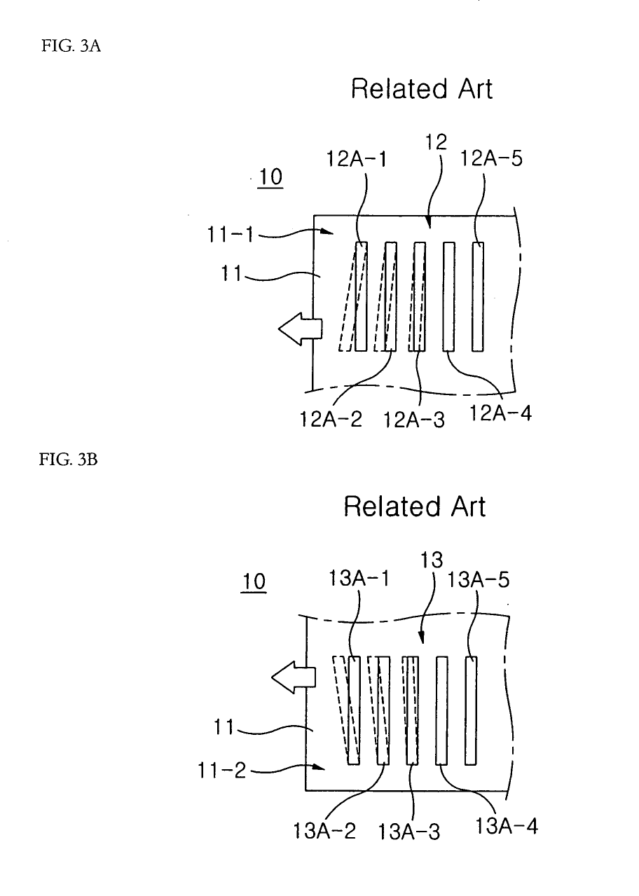

### DESCRIPTION OF EMBODIMENTS

Hereinafter, the preferred embodiments of the present invention will be explained in more detail with reference to the accompanying drawings.

A mask of the present invention includes a plurality of grill sections corresponding to active areas of a substrate. Here, each of the grill sections includes a plurality of grills (patterns) formed on a mask base member, wherein the grills have the same length and width.

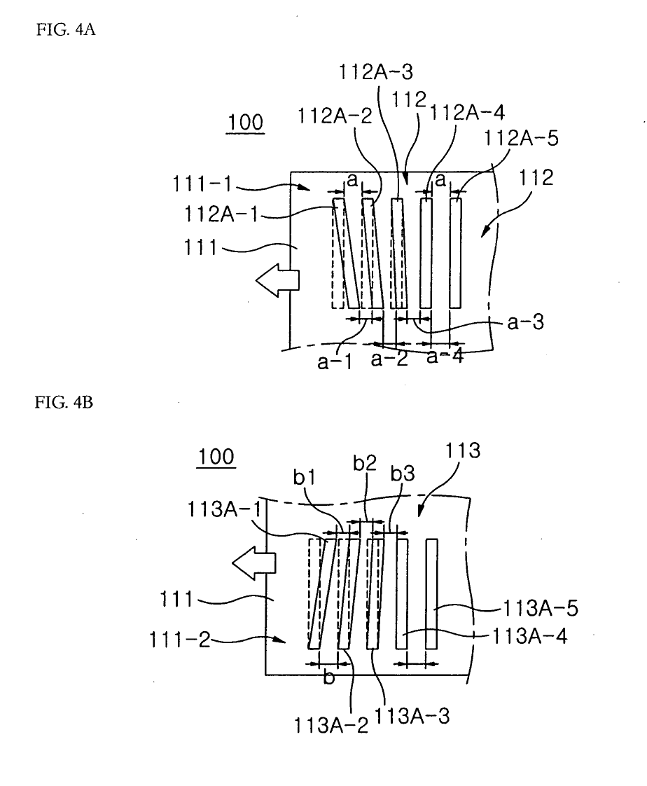

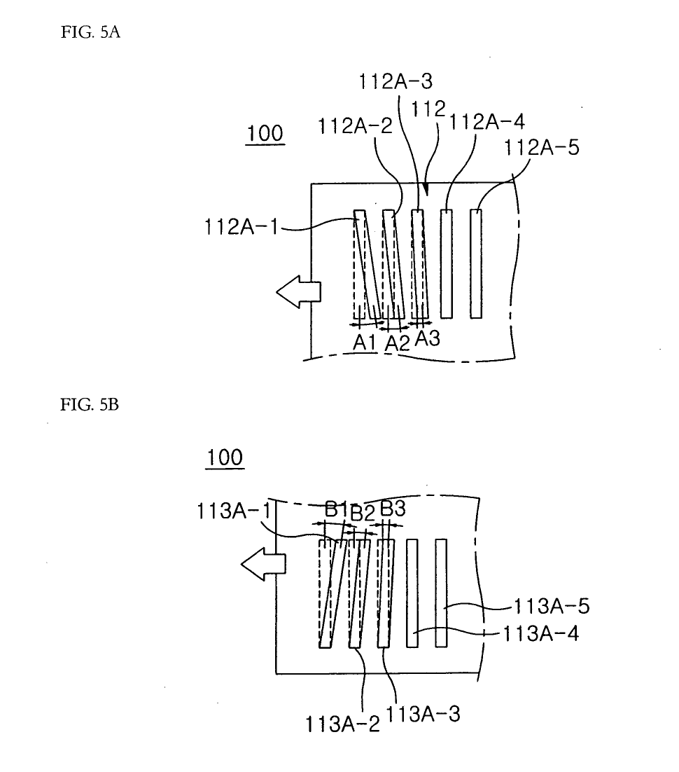

FIG. 4A and FIG. 4B are views illustrating a part of a mask according to one embodiment of the present invention. Particularly, FIG. 4A shows a grill section disposed in upper-left corner of the mask, and FIG. 4B shows a grill section disposed in lower-left corner of the mask. In addition, FIG. 5A and FIG. 5B are views illustrating in detail the grill sections in FIG. 4A and FIG. 4B.

A part or whole of grills 112A-1, 112A-2, 112A-3, 112A-4 and 112A-5 of a grill section 112 disposed in the upper corner of the mask 100 are inclined. In addition, a part or whole of grills 113A-1, 113A-2, 113A-3, 113A-4 and 113A-5 of a grill section 113 disposed in the lower corner of the mask 100 are inclined.

Hereinafter, the structure of the grill sections 112 and 113 will be described in detail with reference to the accompanying drawings.

As shown in FIG. 4A, the grills 112A-1, 112A-2, 112A-3, 112A-4 and 112A-5 are formed in the grill section 112 disposed in the upper-left corner of a mask base member 111 of the mask 100.

Grills, e.g. 112A-1, 112A-2 and 112A-3 of the grills 112A-1, 112A-2, 112A-3, 112A-4 and 112A-5 are inclined toward internal direction of the mask 100 which is opposed to a direction of the stretching force, wherein a stretching force is applied to the grills, e.g. 112A-1, 112A-2 and 112A-3. Particularly, little deformation is occurred to upper portions of the grills 112A-1, 112A-2 and 112A-3 adjacent to an area in which grill is not formed 111-1 (hereinafter, referred to as “solid area”). However, a considerable deformation is occurred to lower portions of the grills 112A-1, 112A-2 and 112A-3.

In the present embodiment, portions separated from the solid area 111-1, i.e. the lower portions of the grills 112A-1, 112A-2 and 112A-3 are inclined toward internal direction of the mask 100 so as to compensate the above deformation of the lower portions of the grills 112A-1, 112A-2 and 112A-3. Here, inclination angles A1, A2 and A3 are high in order of the grills 112A-1, 112A-2 and 112A-3 as shown in FIG. 5A, wherein the inclination angle means angle between an imaginary line extended vertically from the upper portion of corresponding grill and the grill as shown in FIG. 5A.

As a result, spaces (a) between the upper portions of the grills 112A-1, 112A-2, 112A-3, 112A-4 and 112A-5 have the same lengths. However, the more the grills 112A-1, 1122A-2, 112A-3, 112A-4 and 112A-5 are disposed in an internal direction of the mask 100, the smaller spaces between the lower portions of the grills 112A-1, 112A-2, 112A-3, 112A-4 and 112A-5 have lengths.

That is, a space (a-1) between a lower portion of the grill 112A-1 and a lower portion of the grill 112A-2 is higher than a space (a-2) between the lower portion of the grill 112A-2 and a lower portion of the grill 112A-3. Further, the space (a-2) is higher than a space (a-3) between the lower portion of the grill 112A-3 and a lower portion of the grill 112A-4.

In another embodiment of the present invention, the grills 112A-4 and 112A-5 may be inclined depending on the magnitude of the stretching force. In this case, inclination angles of the grills 112A-4 and 112A-5 are smaller than that of the grill 112A-3.

In still another embodiment of the present invention, the grills 112A-1, 112A-2 and 112A-3 may have the same inclination angles.

In brief, the grills 112A-1, 112A-2 and 112A-3 are inclined. Here, in case that the stretching force for stretching the mask 100 is applied to the grill section 112 formed in the upper corner of the mask 100 in the direction of arrow in FIG. 4A, the upper portions of the grills 112A-1, 112A-2 and 112A-3 are little deformed by the solid area 111-1. However, the lower portions of the grills 112A-1, 112A-2 and 112A-3 are moved, i.e. deformed toward lateral portion of the mask 100, wherein the deformation is shown as dotted line in FIG. 4A.

In this case, since the lower portions of the grills 112A-1, 112A-2 and 112A-3 are inclined toward the internal direction of the mask 100, the grills 112A-1, 112A-2 and 112A-3 become parallel with the grills 112A-4 and 112A-5, or other internal grills (not shown) by the deformation. Accordingly, though the grills 112A-1 to 112A-3 are deformed by the stretching force, the grills 112A-1 to 112A-3 may have the same shape as normal grills to which the stretching force is not applied.

In the above description, only partial grills 112A-1, 112A-2 and 112A-3 disposed in the lateral portion of the grill section 112 are inclined. However, the every grills 112A-1 to 112A-5 in the grill section 112 may be inclined.

In addition, a grill section adjacent to the grill section 112 formed in the upper corner of the mask base member 111 may have the structure shown in FIG. 4A, and thus the deformation of a portion separated from the solid area, i.e. lower portion of grills included in the grill may be compensated when the stretching force is applied to the grill.

Further, as shown in FIG. 4B, grills, e.g. 113A-1, 113A-2 and 113A-3 of the grills 113A-1 to 113A-5 in the grill section 113 disposed in the lower-left corner of the mask base member 111 are inclined toward the internal direction of the mask 100 that is a direction opposed to the direction of the stretching force, i.e. direction of an arrow.

Portions separated from the solid area 111-2, i.e. upper portions of the grills 113A-1 to 113A-5 are inclined in the direction opposed to the deformation direction by the stretching force like the grill section 112. As a result, the deformation difference between the grills 113A-1 to 113A-5 may be compensated. Here, an inclination angle B1 of the outmost grill 113A-1 to which the stretching force is applied first of the grills 113A-1, 113A-2 and 113A-3 is higher than an inclination angle B2 of the grill 113A-2 as shown in FIG. 5B. Additionally, the inclination angle B2 is higher than an inclination angle B3 of the grill 113A-3. The inclination angle means angle between an imaginary line extended vertically from the lower portion of corresponding grill and the grill as shown in FIG. 5B.

As a result, spaces (b) between the lower portions of the grills 113A-1, 113A-2, 113A-3, 113A-4 and 113A-5 have the same lengths. However, the more the grills 113A-1, 113A-2, 113A-3, 113A-4 and 113A-5 are disposed in an internal direction of the mask 100, the smaller spaces between the upper portions of the grills 113A-1, 113A-2, 113A-3, 113A-4 and 113A-5 have lengths. That is, a space (b-1) between an upper portion of the grill 113A-1 and an upper portion of the grill 113A-2 is higher than a space (b-2) between the upper portion of the grill 113A-2 and an upper portion of the grill 113A-3. Further, the space (b-2) is higher than a space (b-3) between the upper portion of the grill 113A-3 and an upper portion of the grill 113A-4.

In another embodiment of the present invention, the grills. 113A-4 and 113A-5 may be inclined depending on the magnitude of the stretching force. In this case, inclination angles of the grills 113A-4 and 113A-5 are smaller than that of the grill 113A-3.

In still another embodiment of the present invention, the grills 113A-1, 113A-2 and 113A-3 may have the same inclination angles.

In brief, the grills 113A-1, 113A-2 and 113A-3 are inclined. Here, in case that the stretching force for stretching the mask 100 is applied to the grill section 113 formed in the lower corner of the mask 100 in the direction of arrow in FIG. 4B, the upper portions of the grills 113A-1, 113A-2 and 113A-3 are moved, i.e. deformed toward lateral portion of the mask 100, wherein the deformation is shown as dotted line in FIG. 4B.

In this case, since the upper portions of the grills 113A-1, 113A-2 and 113A-3 are inclined toward the internal direction of the mask 100, the grills 113A-1, 113A-2 and 113A-3 become parallel with the grills 113A-4 and 113A-5, or other internal grills (not shown) by the deformation. Accordingly, though the grills 113A-1 to 113A-3 are deformed by the stretching force, the grills 113A-1 to 113A-3 may have the same shape as normal grills to which the stretching force is not applied.

In the above description, only partial grills 113A-1, 113A-2 and 113A-3 disposed in the lateral portion of the grill section 113 are inclined. However, the every grills 113A-1 to 113A-5 in the grill section 113 may be inclined.

In addition, a grill section adjacent to the grill section 113 formed in the lower corner of the mask base member 111 may have the structure shown in FIG. 4B, and thus the deformation of a portion separated from the solid area, i.e. upper portion of grills included in the grill may be compensated when the stretching force is applied to the grill.

In short, though the grills 112A-1 to 112A-5, and 113A-1 to 113A-5 in the grill sections 112 and 113 are deformed by the stretching force in the stretching process, the grills 112-A-1 to 112A-5, and 113A-1 to 113A-5 may be parallel with normal grills to which the stretching force is not applied, i.e. have the same shape as the normal grills. Accordingly, in the process of evaporating an organic layer, the layer may be accurately evaporated on desired portions of a substrate.

On the other hand, only the grill sections 112 and 113 disposed in the upper-left corner and the lower-left corner of the mask 100 are described in the above description. However, grill sections disposed in the upper-right corner and the lower-right corner of the mask 100 have symmetrical structure compared with the grill sections 112 and 113.

A first embodiment may be achieved in a whole or in part by a mask comprising a plurality of grill sections in which at least one grill are formed, wherein some or whole of grills formed in a first grill section of the grills are inclined. Here, the first grill section is one of outmost grill sections of the grill sections.

A second embodiment may be achieved in a whole or in part by a mask comprising a plurality of grill sections in which at least one grill are formed, wherein some or whole of grills disposed in a first grill section of the grills are inclined, and some or whole of grills disposed in a second grill section of the grills are inclined. Here, the first grill section is disposed in upper portion of outmost grill sections of the grill sections, the second grill section is disposed in lower portion of the outmost grill sections, and the inclined grills are inclined toward internal direction of the mask.

As described above, in the mask for manufacture of a display device of the present invention, the grills deformed by the stretching force may have the same shape as normal grills to which the stretching force is not applied in the stretching process. Accordingly, in the process of evaporating an organic layer, the layer may be accurately evaporated on desired portions of a substrate.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A mask comprising:
a plurality of grill sections in each of which at least one grill is formed,wherein some or all of the at least one grill formed in a first grill section is inclined, and wherein the first grill section is one of outermost grill sections of the plurality of grill sections.

2. The mask of claim 1, wherein the first grill section is disposed in upper portion of the outermost grill sections.

3. The mask of claim 2, wherein a second grill section of the plurality of grill sections is disposed in a lower portion of the outermost grill sections, and some or all of the at least one grill formed in the second grill section is inclined.

4. The mask of claim 3, wherein the first and second grill sections are formed in corners of the mask.

5. The mask of claim 4, wherein the first grill section and the second grill section are disposed symmetrically with respect to a center of the mask.

6. The mask of claim 3, wherein the inclined grills formed in the second grill section are inclined toward a center of the mask.

7. The mask of claim 6, wherein the upper portions of the inclined grills formed in the second grill section are inclined toward the center of the mask, and spaces between lower portions of the inclined grills formed in the second grill section are substantially identical.

8. The mask of claim 6, wherein the more the inclined grills formed in the second grill section are disposed toward the center of the mask, the higher and inclination angle of the inclined grills.

9. The mask of claim 1, wherein the inclined grills formed in the first grill section are inclined away from a center of the mask.

10. The mask of claim 9, wherein lower portions of the inclined grills formed in the first grill section are inclined away from the center of the mask.

11. The mask of claim 10, wherein spaces between upper portions of the inclined grills formed in the first grill section are substantially identical.

12. The mask of claim 9, wherein the more the inclined grills formed in the first grill section are disposed away from the center of the mask, the higher an inclination angle of the inclined grills.

13. A process of depositing organic material of a process of manufacturing an organic electroluminescent device utilizing the mask of claim 1.

14. A mask comprising:
a plurality of grill sections in each of which at least one grill is formed, wherein some or all of the at least one grill disposed in a first grill section is inclined and some or all of the at least one grill disposed in a second grill section is inclined, wherein the first grill section is disposed in an upper portion of outermost grill sections of the plurality of grill sections and the second grill section is disposed in a lower portion of the outermost grill sections, and wherein the inclined grills in the first grill section are inclined away from a center of the mask and the inclined grills in the second grill section are inclined toward a center of the mask.

15. The mask of claim 14, wherein the first grill section and the second grill section are disposed symmetrically with respect to the center of the mask.
